(19) United States
(12) Patent Application Publication
(10) Pub. No.: US 2025/0273489 A1
(43) Pub. Date: Aug. 28, 2025

(54) MULTI-STAGE EJECTOR AND METHOD FOR DRIVING THEREOF

(71) Applicant: FLC, Cheonan-si (KR)

(72) Inventors: Ganghyun MUN, Cheonan-si (KR); Sunghee CHO, Asan-si (KR)

(21) Appl. No.: 19/015,624

(22) Filed: Jan. 9, 2025

(30) Foreign Application Priority Data
Jan. 10, 2024 (KR) 10-2024-0004095

(51) Int. Cl. H01L 21/67; H01L 21/683

(52) U.S. Cl. CPC H01L 21/67132; H01L 21/67144; H01L 21/6836; H01L 21/6838; H01L 2221/68322; H01L 2221/68327

(57) ABSTRACT

Disclosed is a multi-stage ejector for separating a pickup-target chip from dicing tape in stages. The multi-stage ejector includes a plurality of ejecting blocks each including a contact portion that comes into contact with dicing tap, a lifting unit including a driving module configured to move the ejecting blocks upward or downward, and a restriction unit configured to limit a lifting height of each of the ejecting blocks. All of the ejecting blocks move upward so that the contact portions come into contact with the dicing tape, and then the ejecting blocks sequentially move downward, starting from the ejecting block having the contact portion positioned at an outermost side, to the same vertical level.

### CROSS-REFERENCE TO RELATED APPLICATION

This application claims priority to Korean Patent Application No. 10-2024-0004095, filed on Jan. 10, 2024, which is incorporated herein by reference in its entirety.

### BACKGROUND

### Technical Field

The present disclosure relates to a multi-stage ejector and a method for driving the multi-stage ejector, and more specifically, to a multi-stage ejector that separates a pickup-target chip from dicing tape in stages, and a method for driving the multi-stage ejector.

### Related Art

In a packaging process, which is a semiconductor back-end process, bonding refers to attaching a wafer chip to a substrate. One type of bonding, die bonding, involves attaching a semiconductor chip onto a lead frame or a printed circuit board (PCB) to establish an electrical connection of the semiconductor chip.

As shown in FIG. 1, in such die bonding, each semiconductor chip C that has undergone a dicing process exists in a state where the semiconductor chip C remains individually positioned and attached to dicing tape T. Typically, the semiconductor chip C is picked up using a plunger P and then placed onto a package substrate. Here, the semiconductor chip C, which is horizontally adhered to dicing tape T, is not easily separated due to adhesive. If excessive suction is applied, physical damage may occur to the semiconductor chip C. Therefore, a solution is needed to facilitate separation of the dicing tape T and the semiconductor chip C.

A structure that enables the separation of the semiconductor chip C is an ejector E. Generally, the ejector E applies pressure to a lower surface of the dicing tape T from beneath with an area smaller than that of the semiconductor chip C while simultaneously holding the dicing tape T by suction, thereby facilitating the separation of the dicing tape T from the semiconductor chip C, and assisting the pickup operation of the plunger P.

A conventional art related to such an ejector (hereinafter referred to as “conventional art”) is disclosed in Korean Patent No. 10-1931127. The conventional technology discloses a semiconductor manufacturing apparatus that includes a lift-up unit that pushes up a die from beneath dicing tape, and a collet that holds the die by suction. The lift-up unit includes a first unit having a plurality of rectangular blocks that contact the dicing tape, and a second unit having a plurality of concentric circular blocks each of which independently transmits up-and-down movement to a corresponding rectangular block. The semiconductor manufacturing apparatus allows the lift-up unit to be easily modified according to the type of products.

However, the conventional technology requires a plurality of vertical driving units corresponding to the number of lift-up blocks (ejecting blocks), leading to excessive costs. Additionally, controlling the multiple lift-up blocks necessitates multi-axis motion position control technology. Therefore, there is a need for technology related to an ejector that has a simple operating structure and enables low-cost implementation.

### SUMMARY

The present disclosure has been devised to solve the above problem, and an object of the present disclosure is to provide a multi-stage ejector that is configured such that a plurality of ejecting blocks move upward as a whole to perform primary separation of an outer periphery of dicing tape, and then each ejecting block moves downward sequentially from an outer side toward a center to achieve sequential separation of the dicing tape from the outer side to the center, thereby realizing multi-stage upward or downward movement particularly through a reduced number of vertical driving units.

A multi-stage ejector according to an embodiment of the present disclosure may include: a plurality of ejecting blocks each including a contact portion that comes into contact with dicing tape; a lifting unit comprising a driving module configured to move the ejecting blocks upward or downward; and a restriction unit configured to limit a lifting height of each of the ejecting blocks. The ejecting blocks may be configured such that all of the ejecting blocks move upward so that the contact portions come into contact with the dicing tape, and then the ejecting blocks sequentially move downward, starting from an ejecting block having the contact portion positioned at an outermost side, to an identical vertical level (hereinafter, referred to as a descending mode), or all of the ejecting blocks move upward so that the contact portions come into contact with the dicing tape, and then some of the ejecting blocks additionally move upward simultaneously, from a second ejecting block provided inward of a first ejecting block positioned at an outer side to a central ejecting block positioned at the innermost side, and thereafter, the ejecting blocks from the second ejecting block to the central ejecting block, sequentially move downward to the identical vertical level (hereinafter, referred to as an ascending mode).

Furthermore, a vertical descending level of the ejecting blocks may be formed at a standby position formed in an ejector hood.

The lifting unit may further include a lifting block provided below the central ejecting block disposed at an innermost side among the ejecting blocks. The driving module may include a first driving module configured to move the central ejecting block upward or downward, and a second driving module configured to move the lifting block upward or downward.

The lifting unit may further include a connection pin installed to connect each of the ejecting blocks and the lifting block.

The restriction unit may include a downward movement restriction unit configured to limit descent heights of the ejecting blocks, and a spacing restriction unit configured to limit a maximum spacing between the ejecting blocks.

The downward movement restriction unit may include a coupling element coupled to the connection pin, an elastic element configured to be compressed by the coupling element, and a support element provided under the elastic element.

The interlocking hole may include an increased-width recess formed downward from an upper portion of the disc, and a reduced-width hole formed to penetrate both a bottom of the increased-width recess and a lower portion of the disc, the reduced-width hole having a width smaller than a width of the increased-width recess. A vertical distance (hereinafter, referred to as an inner vertical distance) between a lower surface of the support element positioned in the increased-width recess of the interlocking hole of an inner ejecting block and the bottom of the increased-width recess of the interlocking hole of the inner ejecting block is greater than a vertical distance (hereinafter, referred to as an outer vertical distance) between a lower surface of the support element positioned in the increased-width recess of the interlocking hole of an outer ejecting block positioned outward of the inner ejecting block, and the bottom of the increased-width recess of the interlocking hole of the outer ejecting block.

The vertical distance (distance a) of a first ejecting block having the contact portion positioned at the outermost side among the plurality of ejecting blocks may be a zero (0), the vertical distance of a second ejecting block disposed inward of the first ejecting block may correspond to distance a, and the vertical distance of the central ejecting block provided inward of the second ejecting block may be twice distance a.

The spacing restriction unit may include a bolt that passes through the first ejecting block and is fastened to the central ejecting block, or a bolt that passes through the second ejecting block and is fastened to the central ejecting block.

The bolt may include a head portion having a diameter larger than a diameter of a through-hole formed in the first ejecting block or the second ejecting block, a body portion that is connected to the head portion and has a diameter smaller than or equal to the diameter of the through-hole, and a threaded portion that is connected to the body portion and engaged with a threaded hole formed in the central ejecting block.

When all of the ejecting blocks move upward, a peripheral side portion of a chip may be separated from the dicing tape.

A method of driving a multi-stage ejector according to an embodiment of the present disclosure may include: moving upward all of a plurality of ejecting blocks, each including a contact portion that comes into contact with dicing tape, so that the ejecting blocks are exposed outside an ejector hood, and pressing the dicing tape from below; sequentially moving downward some of the plurality of ejecting blocks, starting from a first ejecting block disposed at an outermost side among the plurality of ejecting blocks to an ejecting block disposed outward of a central ejecting block disposed at an innermost side, by a lifting unit including a driving module configured to move the plurality of ejecting modules upward or downward; and moving the central ejecting block downward by the lifting unit.

Furthermore, a vertical descending level of the ejecting blocks may be formed at a standby position formed in the ejector hood.

The lifting unit may further include a lifting block provided below the central ejecting block, and stepwise downward movement of the ejecting blocks may be performed by moving the lifting block downward.

Interlocked downward movement of the lifting block and each of the ejecting blocks may be performed using a connection pin installed to connect each of the ejecting blocks and the lifting block.

### BRIEF DESCRIPTION OF THE DRAWINGS

FIG. 1 is a diagram illustrating a concept of an ejector.

FIGS. 2 to 11 relate to embodiments of the present disclosure, and FIG. 2 is a diagram of an external shape of a multi-stage ejector according to the present disclosure.

FIG. 3 separately illustrates an outermost ejecting block.

FIG. 4 separately illustrates an intermediate ejecting block.

FIG. 5 separately illustrates an innermost ejecting block.

FIG. 6 is a plan view illustrating an upper surface of the ejector.

FIGS. 7 to 9 are cross-sectional views illustrating the multi-stage ejector.

FIG. 10 is a diagram illustrating an operation sequence (descending mode) according to the present disclosure.

FIG. 11 is a diagram for describing a method of driving the multi-stage ejector.

FIG. 12 is a diagram illustrating an operation sequence (ascending mode) according to the present disclosure.

### DETAILED DESCRIPTION

While the present disclosure is susceptible to various modifications and alternative forms, embodiments (implantations) thereof will be described herein in detail. However, this is not intended to limit the present disclosure to particular modes of practice, and it should be understood that the present disclosure is to cover all modifications, equivalents, and alternatives falling within the spirit and scope of the present disclosure.

The terminology used herein is for the purpose of describing particular embodiments only and is not intended to be limiting the present disclosure. In the present disclosure, the singular forms are intended to include the plural forms as well, unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terms “first”, “second”, etc. are used only for the purpose for distinguishing a constitutive element from other constitutive elements, but the constitutive element should not be limited to a manufacturing order, and the terms described in the detailed description may not be consistent with those described in the claims.

Before providing a detailed description of the present disclosure, to avoid confusion in terminology, the terminology related to ejecting blocks is defined as follows: the expressions “disposed on an outer side” and “disposed on an inner side” are based on a portion (contact portion) of the ejecting block that is exposed to the outside of an ejector hood. From the perspective of a disc 11, an “ejecting block disposed on the outer side” refers to an “ejecting block disposed on an upper side,” whereas an “ejecting block disposed on the inner side” refers to an “ejecting block disposed on a lower side.” Since the difference in these expressions is based on the contact position relative to the component serving as the reference point, they should be interpreted according to the overall context of the sentence. Such definitions of terms are to be applied equally to the claims unless otherwise specified.

The present disclosure relates to a multi-stage ejector (hereinafter referred to as “the present apparatus”) and a driving method thereof (hereinafter referred to as “the present method”). The present apparatus includes a plurality of ejecting blocks, a lifting unit that moves the ejecting blocks upward or downward, and a restriction unit that limits the lifting height of each ejecting block. Furthermore, the present apparatus may further include a housing that accommodates components, including the ejecting blocks, and an ejector hood 4 that covers an open upper portion of the housing. The present apparatus is configured such that a plurality of ejecting blocks move upward simultaneously and become exposed outside the ejector hood 4, thereby causing a pickup-target chip to separate from dicing tape T at an outer side (outer periphery, peripheral side portion), and then, while pressing a lower surface of the dicing tape T, each of the ejecting blocks moves downward sequentially from the outermost ejecting block to the same vertical level (hereinafter, distance a), so that, ultimately, only the ejecting block disposed at the innermost position remains in contact with the dicing tape T (hereinafter, descending mode), whereby a central ejecting block is positioned highest, and the outermost ejecting block is positioned lowest, thereby forming an approximately mountain-like shape. Such a vertical height difference among the ejecting blocks allows the pickup-target chip to be sequentially separated from the dicing tape T from the outer side toward the center (while the ejecting blocks move downward sequentially) during a process of transferring the semiconductor chip by the plunger.

Alternatively, all of the plurality of ejecting blocks move upward, and while pressing the lower surface of the dicing tape T, the ejecting blocks additionally move upward simultaneously from the outermost ejecting block to the innermost ejecting block. Then, the ejecting blocks sequentially move downward from the ejecting block positioned inward of the outermost ejecting block to the innermost ejecting block until reaching the same vertical level (hereinafter, ascending mode), thereby enabling sequential separation and facilitating the separation of the semiconductor chip from the dicing tape T. Hereinafter, the present disclosure will be described in detail with reference to the accompanying drawings through embodiments of the present disclosure.

The following description provides an example based on the sequential downward movement of the ejecting blocks positioned at the outer side (the descending mode); however, the present disclosure does not exclude the aforementioned ascending mode.

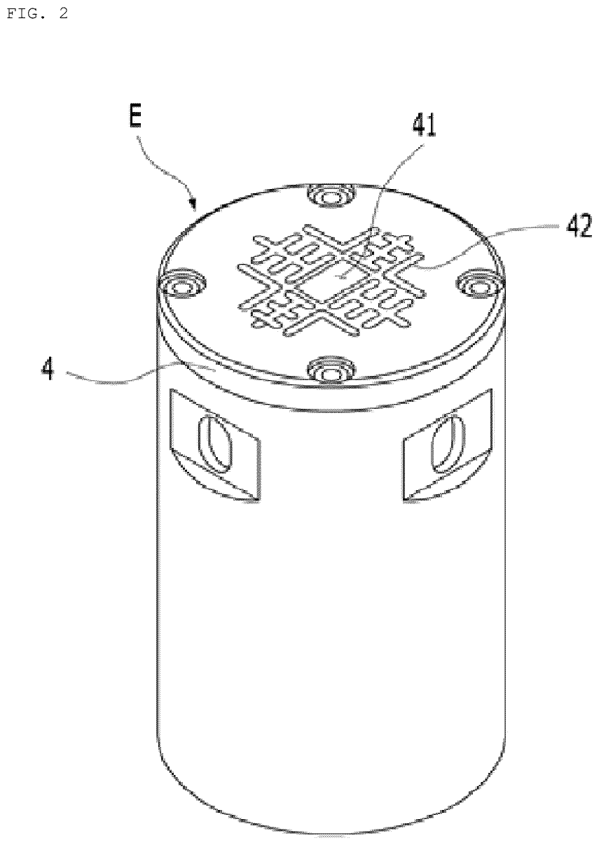

FIGS. 2 to 7 are diagrams illustrating embodiments of a multi-stage ejector according to the present disclosure. As shown in drawings, the present apparatus includes a plurality of ejecting blocks each having a contact portion that comes into contact with the dicing tape T. Furthermore, the ejecting blocks may include a central ejecting block CB having a contact portion positioned at the innermost side, a second ejecting block BB positioned outward thereof, and a first ejecting block OB having a contact portion positioned at the outermost side. In the accompanying drawings, an example is illustrated in which the ejecting blocks are configured with a total of three blocks. However, it is assumed that the number of the ejecting blocks may be varied as needed, including embodiments in which the number of the second ejecting blocks BB is configured as two, three, or more.

In the present disclosure, the ejecting blocks are characterized in that all of the ejecting blocks move upward so that the contact portions come into contact with the dicing tape T, and then the ejecting blocks sequentially move downward, starting from the ejecting block having the contact portion at the outermost side, to the same vertical level (distance a) (hereinafter, referred to as a descending mode). In other words, the ejecting blocks move downward sequentially from the outer side to the same level, so that ultimately only the ejecting block positioned at the center remains in contact with the dicing tape T, thereby causing the dicing tape T to be separated sequentially from the outer side thereof inward.

Alternatively, the ejecting blocks are characterized in that all of the ejecting blocks move upward so that the contact portions come into contact with the dicing tape T, and then the ejecting blocks additionally move upward simultaneously from the first ejecting block OB positioned at the outer side to the central ejecting block CB, and thereafter, some of the ejecting blocks from the second ejecting block BB to the central ejecting block CB sequentially move downward to the same vertical level (distance a) (hereinafter, referred to as an ascending mode).

Furthermore, in this case, the vertical descending level of each of the ejecting blocks is configured to be the same. The vertical descending level may be formed at a standby position inside the ejector hood 4. That is, when each of the ejecting blocks moves downward sequentially, the ejecting block moves downward to the standby position inside the ejector hood 4. In other words, it can be seen that each of the ejecting blocks is aligned at the standby position through sequential downward movement.

As a specific embodiment related to the ejecting blocks, the first ejecting block OB, which is positioned at the outermost side among the ejecting blocks, may include a disc 11, a flange 12 vertically connected to a lower portion of the disc 11, a pusher 13 that is vertically connected to an upper portion of the disc 11 and forms a contact portion on an upper surface thereof, a through-hole 14 formed in a recess exposed upward, the recess being depressed in the disc 11 toward the flange 12, and an interlocking hole 15 formed in the disc 11 to facilitate connection with the operation of the second ejecting block.

Specifically, the disc 11 is a disc-shaped body that serves as a base of the ejecting block. The disc shape corresponds to an overall cylindrical shape of the present apparatus; however, it is not necessarily required to be formed in a disc shape. Although the disc 11 may have various forms, including polygonal or irregular shapes, it is preferable to have a somewhat standardized shape, such as a disc or a polygonal plate, to ensure the stability in upward or downward movement of the block.

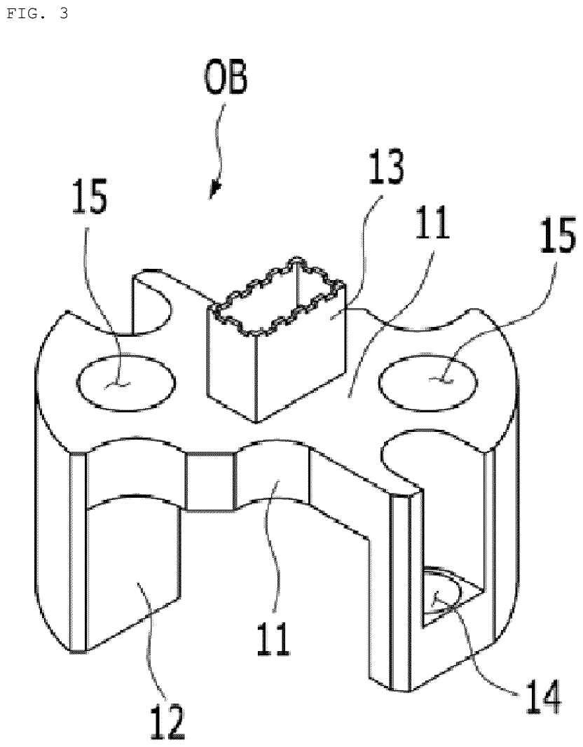

As illustrated in FIG. 3, the disc 11 may include an engagement portion 111 in which a partial section along the outer periphery is cut. The engagement portion 111 may be configured to include an engagement surface formed by a combination of a curved surface and a flat surface. The engagement portion 111 may also be formed in the second ejecting block BB, which will be described later, and the two engagement portions 111 may be formed at positions that do not overlap each other. Through the engagement portions 111, despite a difference in placement heights of the discs 11 of the first ejecting block OB and the second ejecting block BB, installation heights of a connection pin 22, a coupling element 31, and a bolt 33, which are connected to the central ejecting block CB disposed at a lowest position, may be configured to be the same or similar.

The flange 12 is configured to extend downward from a lower portion of the disc 11 to enclose the disc 11 of the second ejecting block BB positioned below. A hollow space, in which the second ejecting block BB is accommodated, is formed at the center, and the flange 12 is disposed around the hollow space.

The pusher 13 is configured to contact the dicing tape T and push up the dicing tape T, with an upper surface of the pusher 13 serving as a contact portion that comes into contact with the dicing tape T. The pusher 13 may be configured in a rectangular pillar shape according to the shape of the dicing tape T but is not necessarily limited thereto. In addition, the contact portion, which is the upper surface of the pusher 13, may have a concave-convex structure in which protrusions and recesses are alternately arranged. The concave-convex structure maintains pressing efficiency on the dicing tape T while allowing the pusher 13 to easily detach from a lower surface of the dicing tape T when the pressing force is released.

The through-hole 14 is configured to allow passage of the bolt 33, which will be described later. The bolt 33 passing through the through-hole 14 is engaged with a threaded hole in the central ejecting block CB, thereby limiting a gap between the first ejecting block OB and the central ejecting block CB to a certain distance or less during interlocked upward or downward movement.

The interlocking hole 15 is configured to allow passage of the coupling element 31 and the connection pin 22, which will be described later, so that an interlocking assembly, in which the coupling component 31 and the connection pin 22 are coupled, passes through the interlocking hole 15. The connection pin 22 passes through a fixing hole in the central ejecting block CB and is secured to a lifting block 21, thereby enabling the first ejecting block OB to move downward in an interlocked manner as the lifting block 21 moves downward.

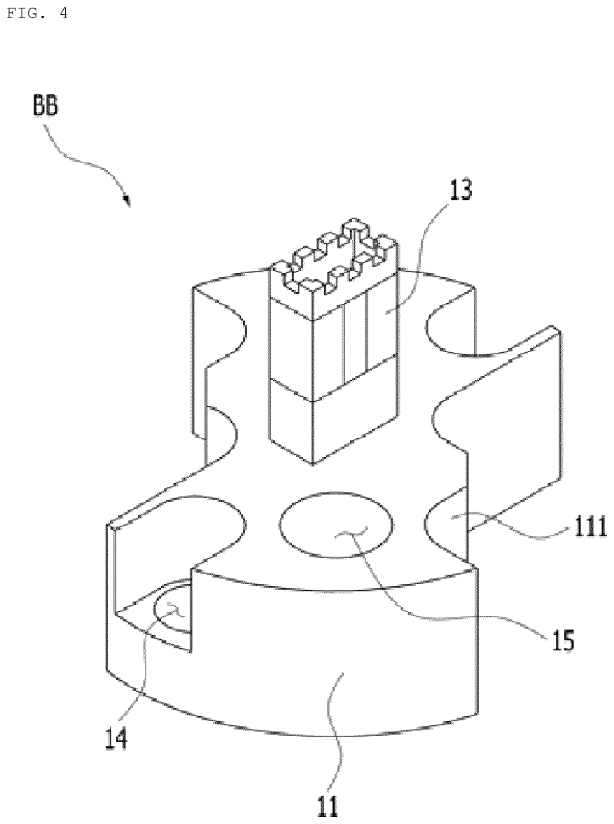

As a specific embodiment related to the ejecting blocks, as illustrated in FIG. 4, the second ejecting block BB, which is positioned in the intermediate position among the ejecting blocks, may include the disc 11, a pusher 13 that is vertically connected to an upper portion of the disc 11 with a contact portion formed on an upper surface of the pusher 13, a through-hole 14 formed in a recess that is depressed downward in the disc 11 and exposed upward, and an interlocking hole 15 formed in the disc 11. The second ejecting block BB, unlike the first ejecting block OB, does not need to accommodate a disc 11 of the central ejecting block CB positioned below, and therefore does not include a flange 12.

The disc 11, the pusher 13, the through-hole 14, and the interlocking hole 15 are not significantly different from the corresponding components of the first ejecting block OB mentioned above, and therefore, redundant descriptions are omitted. However, the pusher 13 of the second ejecting block BB is configured to be longer than the pusher 13 of the first ejecting block OB, as the contact portion of each ejecting block is required to be positioned at the same height at the standby position.

Furthermore, as described above, the engagement portion 111 of the second ejecting block BB is formed at a position that does not overlap with the engagement portion 111 of the first ejecting block OB, and the through-hole 14 and the interlocking hole 15 are also formed at positions that do not overlap with those of the first ejecting block OB. Specifically, the heights at which the through-hole 14 and the interlocking hole 15 are formed in the second ejecting block BB are the same as or similar to those in the first ejecting block OB. This configuration ensures that, despite the difference in the placement heights of the discs 11 of the first ejecting block OB and the second ejecting block BB, the installation heights of the connection pin 22, the coupling element 31, and the bolt 33, which are connected to the central ejecting block CB disposed at the lowest position, can be the same or similar.

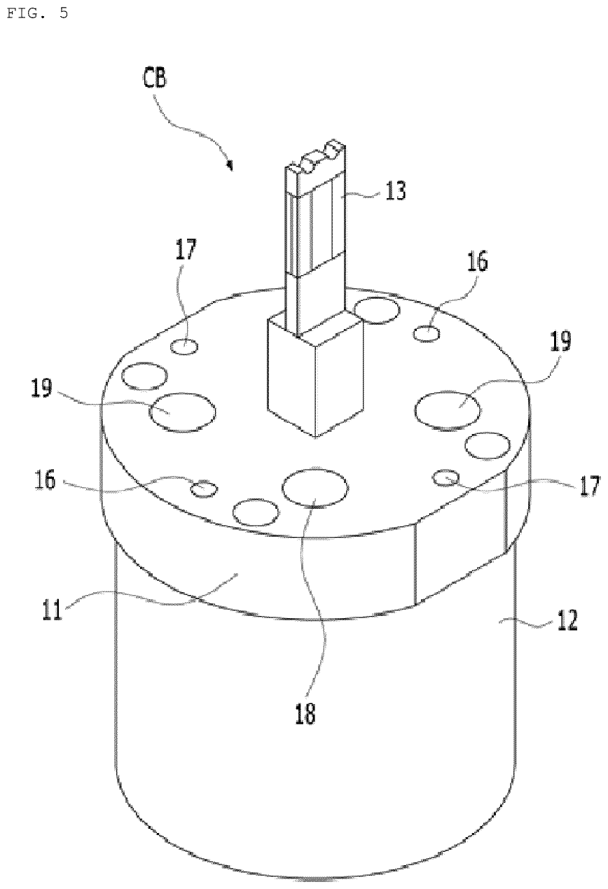

As a specific embodiment related to the ejecting blocks, as illustrated in FIG. 5, the central ejecting block CB, which is positioned at the innermost side among the ejecting blocks, includes the disc 11, a flange 12 vertically connected to a lower portion of the disc 11, a pusher 13 vertically connected to an upper portion of the disc 11 with a contact portion formed on an upper surface of the pusher 13, and a first threaded hole 16, a second threaded hole 17, a first fixing hole 18, and a second fixing hole 19, which are formed in the disc 11.

The other ejecting blocks also include the same configuration as the disc 11, the flange 12, and the pusher 13. Similar to the coupling relationship between the central ejecting block CB and the disc 11, the flange 12, and the pusher 13, a coupling structure between each of the other ejecting blocks and the disc 11, the flange 12, and the pusher 13 is formed. However, to align the heights of the contact portions, the length of the pusher 13 of the central ejecting block CB may be formed to be the longest compared to the pushers of the other ejecting blocks. Furthermore, the flange 12 of the central ejecting block CB is configured to have therein a follow space formed in a continuous shape along the outer periphery thereof. The lifting block 21, described later, is accommodated in the hollow space.

The first threaded hole 16 is formed at a position corresponding to the through-hole 14 of the second ejecting block BB, and the second threaded hole 17 is formed at a position corresponding to the through-hole 14 of the first ejecting block OB. Accordingly, a threaded portion 333 of the bolt 33 that has passed through the through-hole 14 of the second ejecting block BB is threadedly engaged with and secured to the first threaded hole 16, while the threaded portion 333 of the bolt 33 that has passed through the through-hole 14 of the first ejecting block OB is threadedly engaged with and secured to the second threaded hole 17.

The first fixing hole 18 is formed at a position corresponding to the interlocking hole 15 of the second ejecting block BB, and the second fixing hole 19 is formed at a position corresponding to the interlocking hole 15 of the first ejecting block OB. Accordingly, the connection pin 22 that has passed through the interlocking hole 15 of the second ejecting block BB passes through the first fixing hole 18 and is threadedly engaged with and secured to the lifting block 21, while the connection pin 22 that has passed through the interlocking hole 15 of the first ejecting block OB passes through the second fixing hole 19 and is threadedly engaged with and secured to the lifting block 21. Here, although threaded engagement is selected as the secured coupling between the connection pin 22 and the lifting block 21, which adopts a widely used and simple coupling scheme, the coupling is not necessarily limited to the threaded engagement.

Next, the present apparatus may further include a lifting unit configured to achieve the upward or downward movement of the ejecting blocks. The lifting unit may include a driving module that moves the ejecting blocks upward or downward. The driving module may broadly include a configuration that physically moves the ejecting blocks upward or downward and a configuration that provides power. The configuration that physically moves the ejecting blocks upward or downward may be a configuration that is directly coupled to the blocks and moves the blocks upward or downward, such as a piston rod or a pushing plate. The configuration that provides power may employ various structures, such as a hydraulic cylinder system, a pneumatic cylinder system, or a motor-driven system, and the present disclosure does not particularly limit the type thereof.

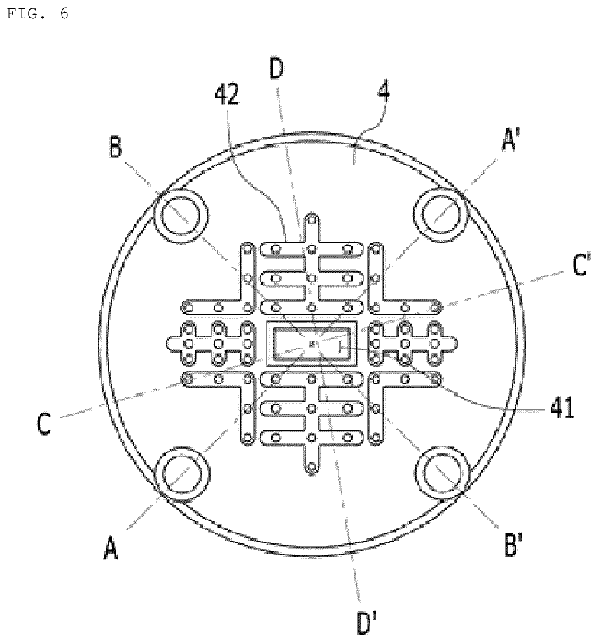

As a specific embodiment, as illustrated in FIGS. 6 to 9, the lifting unit may further include a lifting block 21 provided below the central ejecting block CB, which is positioned at the innermost side among the plurality of ejecting blocks. The lifting block 21 has a shape similar to that of the disc 11 of the ejecting block and may have a shape corresponding to the hollow space of the central ejecting block CB so as to be inserted into the hollow space of the central ejecting block CB. The lifting block 21 moves upward or downward by a second driving module, described later. During upward movement, the lifting block 21 pushes up all of the ejecting blocks, including the central ejecting block CB so that the ejecting blocks move upward. During downward movement, the lifting block 21 pulls down each of the ejecting blocks except for the central ejecting block CB through the connection pin 22 so that each of the corresponding ejecting blocks moves downward.

The driving module may include a second driving module that moves the lifting block 21 upward or downward, and a first driving module that moves the central ejecting block CB upward or downward. The second driving module is provided below the lifting block 21 to move the lifting block 21 upward or downward, thereby moving upward all the ejecting blocks, including the lifting block 21, or moving downward all of the ejecting blocks except for the central ejecting block CB.

Furthermore, the first driving module moves all the ejecting blocks upward or downward by moving the central ejecting block CB, which is positioned at the innermost side, upward or downward.

In other words, when the second driving module moves the lifting block 21 upward, all of the ejecting blocks move upward, and when the second driving module moves the lifting block 21 downward, each of the ejecting blocks moves downward sequentially. Additionally, when the first driving module moves the central ejecting block CB upward or downward, all of the ejecting blocks move upward or downward simultaneously.

The present disclosure, compared to a structure equipped with a single vertical driving unit, primarily enables separation of the outer periphery of the dicing tape T, followed by the separation of the dicing tape toward the central portion in stages, thereby allowing more reliable and easier separation of the dicing tape T. Furthermore, because only two vertical driving units are provided, the present disclosure may not only reduce costs compared to providing a vertical driving unit for each ejecting block but may also simplify a control algorithm of the vertical driving units. Additionally, because driving positions of the two vertical driving units can be motion-controlled, the lifting height of all of the ejecting blocks can be precisely adjusted. Although will be described later, an ejecting process can be performed based on a scheme selected between the ascending scheme and the descending scheme according to a control sequence.

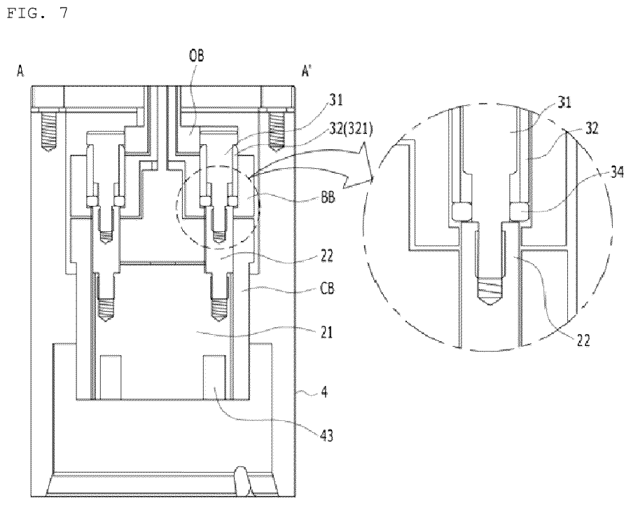

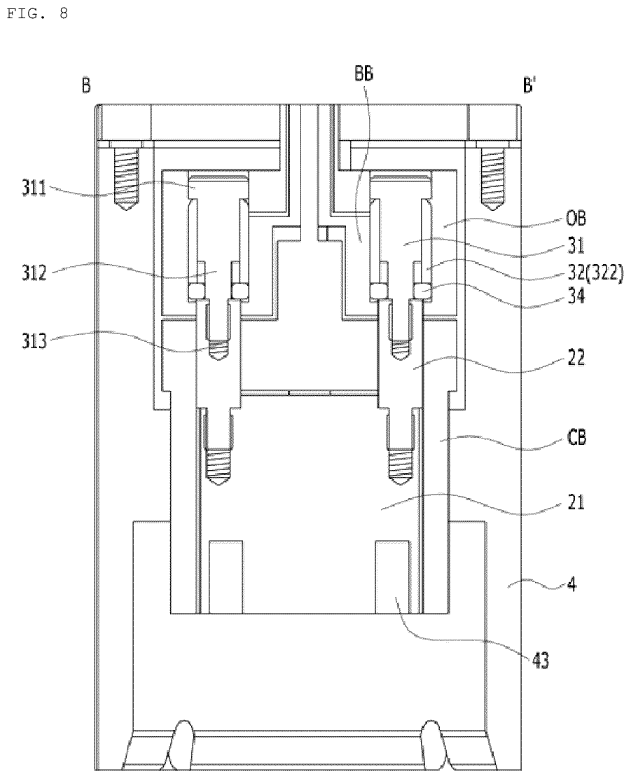

Furthermore, according to an embodiment of the present disclosure, as illustrated in FIGS. 6 to 9, the lifting unit may further include the connection pin 22 installed to connect each of the ejecting blocks to the lifting block 21. The connection pin 22 has an upper portion coupled to the coupling element 31, described later, passes through the interlocking hole 15 of each of the ejecting blocks and the fixing hole of the central ejecting block CB, and has a lower portion that is threadedly engaged with the lifting block 21. In FIG. 7, an interlocked operating state of the first ejecting block OB and the lifting block 21 through the connection pin 22 is shown, while in FIG. 8, an interlocked operating state of the second ejecting block BB and the lifting block 21 through the connection pin 22 can be observed. Through the connection pin 22, each of the ejecting blocks moves downward in an interlocked manner as the lifting block 21 moves downward.

Next, as illustrated in FIGS. 6 to 9, the present apparatus may further include a restriction unit configured to limit the lifting height of each of the ejecting blocks. The restriction unit may include a downward movement restriction unit that limits a descent height of each of the ejecting blocks, and a spacing restriction unit that limits a maximum spacing between the ejecting blocks. The downward movement restriction unit restricts the descent height of each of the ejecting blocks during the downward movement of the ejecting block so that the ejecting block does not move downward below a certain level, thereby ensuring the implementation of the same-level descending operation, which is a key feature of the present disclosure. The spacing restriction unit enables simultaneous upward or downward movement of the ejecting blocks by limiting the maximum spacing between the ejecting blocks.

As a specific embodiment of the downward movement restriction unit, as illustrated in FIGS. 6 to 9, the downward movement restriction unit may include the coupling element 31 coupled to the connection pin 22. The coupling element 31 is provided inside the disc 11 in which the interlocking hole 15 is formed. A lower end of the coupling element 31 passes through the interlocking hole 15 and is coupled to the connection pin 22. For example, the coupling between the coupling element 31 and the connection pin 22 may be achieved by threaded engagement but is not necessarily limited thereto.

As illustrated in FIGS. 6 to 9, the downward movement restriction unit may further include an elastic element 32 that is compressed by the coupling element 31. The elastic element 32 is provided inside the disc 11, in which the interlocking hole 15 is formed, together with the coupling element 31, and is configured to have an outer diameter larger than the interlocking hole 15 to prevent the elastic element 32 from being detached from inside the disc 11.

As a specific embodiment related to the coupling element 31 and the elastic element 32, as illustrated in FIG. 8, the coupling element 31 may include a large-diameter portion 311 provided at an upper portion, a small-diameter portion 312 connected to a lower portion of the large-diameter portion 311 and having a relatively small diameter, and a threaded portion 313 provided on a lower portion of the small-diameter portion 312. The large-diameter portion 311 is configured to have a diameter larger than an inner diameter of the elastic element 32 and, preferably, may have a diameter equal to or greater than the outer diameter of the elastic element 32. The small-diameter portion 312 is configured to have a diameter equal to or smaller than the inner diameter of the elastic element 32, thereby allowing the elastic element 32 to be coupled around the circumference of the small-diameter portion 312. The threaded portion 313 is not restricted in diameter; however, both the small-diameter portion 312 and the threaded portion 313 are configured to have a diameter smaller than that of the interlocking hole 15 so that the small-diameter portion 312 and the threaded portion 313 can pass through the interlocking hole 15. For reference, FIG. 8 illustrates an embodiment in which the small-diameter portion 312 is configured with a stepped structure, allowing the elastic element 32 to be coupled to a relatively larger-diameter upper portion thereof, while a relatively smaller-diameter lower portion thereof passes through the interlocking hole 15. Through the coupling element 31 and the elastic element 32, when the connection pin 22 moves downward by the downward movement of the lifting block 21, the coupling element 31, which is secured to the connection pin 22 via the threaded portion 313, moves downward together. At this time, the large-diameter portion 311 compresses the elastic element 32, and the downward movement is restricted at a certain height, as the downward movement cannot indefinitely proceed due to the elastic force and the maximum physical compression length of the elastic element 32.

Additionally, as shown in FIGS. 7 to 8, the present apparatus may further include a support element 34 provided on an outer surface of the coupling element 31 and positioned below the elastic element 32. The support element 34 not only provides supporting force against the compression of the elastic element 32 but also prevents detachment or shaking of the elastic element 32. Furthermore, the support element 34 enhances the reliability of the coupling element 31 in linear motion during the upward or downward movement.

More specifically, the interlocking hole 15 may include an increased-width recess formed downward from the upper portion of the disc 11 and a reduced-width hole that penetrates both the bottom of the increased-width recess and the lower portion of the disc 11 and has a width (diameter) smaller than that of the increased-width recess.

The interlocking hole 15 may form a stepped structure by including the increased-width recess and the reduced-width hole.

In the case where all of the ejecting blocks move upward and the contact portions come into contact with the dicing tape T, the upper portion of the connection pin 22, which is coupled to the coupling element 31, may be positioned above the bottom of the increased-width recess. Here, the support element 34 may be disposed on the connection pin 22 and positioned in the increased-width recess.

The support element 34 may, for example, enclose the coupling element 31, and an outer diameter thereof is larger than that of the reduced-width hole, causing the support element 34 to engage with the stepped structure, thereby preventing the support element 34 from passing through the reduced-width hole.

As described above, it has been stated that the support element 34 may be positioned on the upper portion of the connection pin 22 when all of the ejecting blocks move upward and the contact portions come into contact with the dicing tape T. In this case, a vertical distance is formed between a lower surface of the support element 34 and the bottom of the increased-width recess.

The downward movement restriction unit is provided between the central ejecting block CB and each of the remaining ejecting blocks. For convenience of explanation, the downward movement restriction unit positioned between the central ejecting block CB and the first ejecting block OB will be referred to as a first downward movement restriction unit, and the downward movement restriction unit positioned between the central ejecting block CB and the second ejecting block BB will be referred to as a second downward movement restriction unit.

Here, the vertical distance (hereinafter, referred to as an inner vertical distance) between the lower surface of the support element 34 positioned in the increased-width recess of the interlocking hole 15 of an inner ejecting block (for example, the second ejecting block BB) and the bottom of the increased-width recess of the interlocking hole 15 of the inner ejecting block may be greater than the vertical distance (hereinafter, referred to as an outer vertical distance) between the lower surface of the support element 34 positioned in the increased-width recess of the interlocking hole 15 of an outer ejecting block (for example, the first ejecting block OB) and the bottom of the increased-width recess of the interlocking hole 15 of the outer ejecting block, which is positioned outward of the inner ejecting block.

For example, the inner vertical distance may be a multiple of the outer vertical distance.

More specifically, the vertical distance of the first ejecting block OB may be zero (0), the vertical distance of the second ejecting block BB may correspond to distance a, and the vertical distance of the central ejecting block CB may be twice distance a.

The lifting block 21 is provided with a permanent magnet 43, and as the second driving module moves downward, the lifting block 21 is moved downward by the permanent magnet 43, causing the connection pin 22, which is threadedly engaged with the lifting block 21, to move downward.

As described above, since the outer vertical distance is shorter than the inner vertical distance, the support element 34 inserted into the interlocking hole 15 of the outer ejecting block is positioned on the bottom of the increased-width recess. Accordingly, the outer vertical distance becomes zero, and the gap between the disc 11 of the outer ejecting block and the disc 11 of the inner ejecting block also becomes zero.

Subsequently, when the lifting block 21 moves further downward, the spring force of the elastic element 32 inserted into the interlocking hole 15 of the outer ejecting block is applied to the outer ejecting block, since the gap between the disc 11 of the outer ejecting block and the disc 11 of the inner ejecting block is zero. As a result, the outer ejecting block presses the inner ejecting block downward, whereby the inner ejecting block moves downward until the inner vertical distance becomes zero, and the disc 11 of the inner ejecting block also comes into contact with the disc 11 of the ejecting block positioned inward of the inner ejecting block.

Here, even if the lifting block 21 moves further downward, the inner ejecting block does not move downward any further. The elastic element 32 inserted into the interlocking hole 15 of the inner ejecting block is compressed by the additional descent length, allowing the outer ejecting block and the inner ejecting block to move downward to the same level.

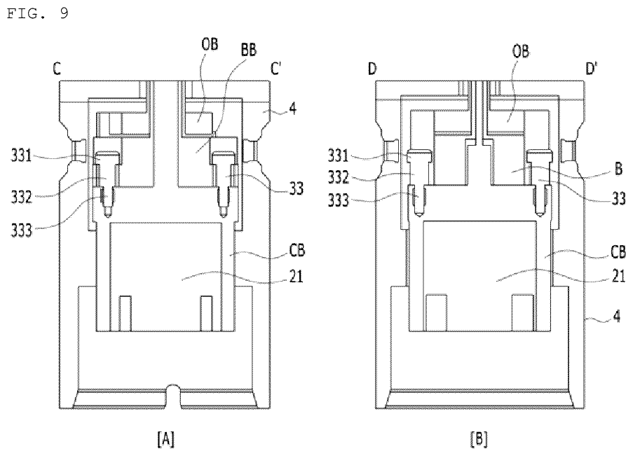

As a specific embodiment of the spacing restriction unit, as illustrated in FIG. 9, the spacing restriction unit may include the bolt 33 that passes through the first ejecting block OB and is fastened to the central ejecting block CB, or passes through the second ejecting block BB and is fastened to the central ejecting block CB.

Particularly, referring to FIG. 9, the bolt 33 may include a head portion 331 having a diameter larger than that of the through-hole 14 (counterbore hole) formed in the first ejecting block OB or the second ejecting block BB, a body portion 332 that is connected to the head portion 331 and has a diameter smaller than or equal to that of the through-hole 14, and a threaded portion 333 (e.g., with an external thread) that is connected to the body portion 332 and engaged with a threaded hole formed in the central ejecting block CB (e.g., a threaded hole with an internal thread). The body portion 332 serves as a non-threaded section having no thread formed, and as a result, the spacing between the ejecting blocks is adjusted according to the length of the body portion 332. In the case where the spacing restriction unit is implemented using the bolt 33 as described above, if the central ejecting block CB moves upward and comes into contact with the second ejecting block BB, the bolt 33 is positioned relatively higher with respect to the second ejecting block BB, causing the second ejecting block BB to be positioned closer to the threaded portion 333. In this state, when the central ejecting block CB moves downward, the head portion 331 of the bolt 33 engages with a portion defining the through-hole 14 of the second ejecting block BB, causing the central ejecting block CB and the second ejecting block BB to move downward in an interlocked manner. The state in which the through-hole 14 and the head portion 331 are in contact determines the maximum spacing between the central ejecting block CB and the second ejecting block BB, preventing further separation therebetween. In other words, the bolt 33 ensures that all of the ejecting blocks move downward together in an interlocked manner when the central ejecting block CB is moved downward by the first driving module.

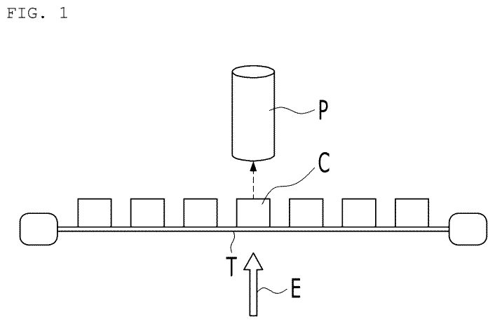

Next, the present apparatus may further include a housing that receives the components, including the ejecting blocks, and the ejector hood 4 that covers an open upper portion of the housing. In FIGS. 1 and 6, the ejector hood 4 and an upper plate of the ejector hood 4 are illustrated. The ejector hood 4 may include, in an upper surface thereof, a suction port 41 provided to secure a lower surface of the dicing tape T by suction and an exposed portion 42 provided at the center to allow the ejecting blocks to be exposed. In the attached drawings, an embodiment is illustrated in which the exposed portion 42 is configured in a rectangular shape, and the suction port 41 is configured as holes arranged uniformly around the exposed portion 42. However, it is assumed that the configuration is not necessarily limited to the aforementioned shape.

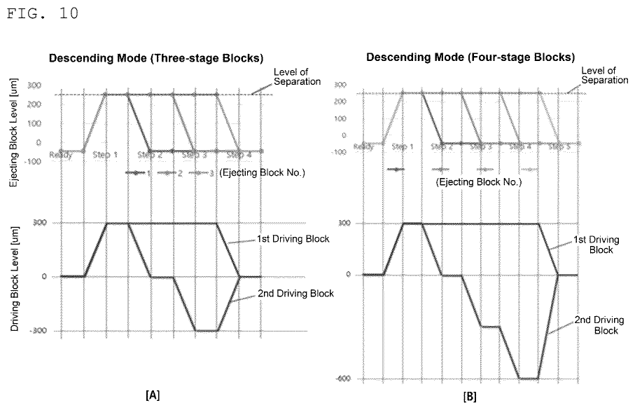

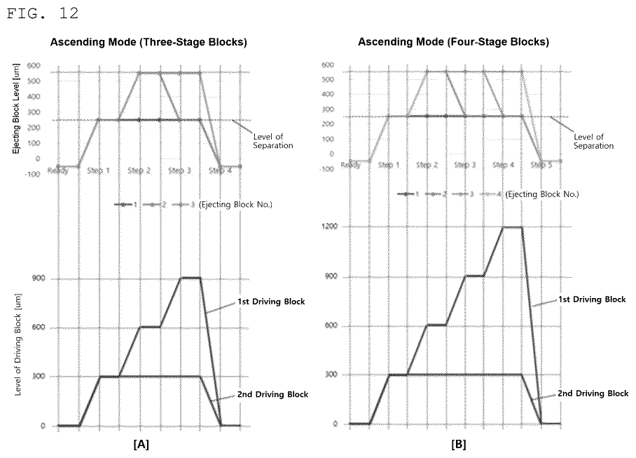

FIG. 10 is a diagram illustrating an operation sequence (descending mode) according to the present disclosure. FIG. 12 is a diagram illustrating an operation sequence (ascending mode) according to the present disclosure. As illustrated in FIG. 10, when a first step (Step 1) is reached in a preparation stage, all of the ejecting blocks move upward, and the heights of the contact portions become equal to or greater than an outer peripheral separation level. That is, all of the ejecting blocks protrude above the exposure portion 42 of the ejector hood 4, so that the contact portions come into contact with the lower surface of the dicing tape T. Here, as illustrated in the lower diagram of FIG. 8, both the second driving module, which moves the lifting block 21 upward or downward, and the first driving module, which moves the central ejecting block CB upward or downward, move upward. Here, the upward movement of the first driving module may be dependent on the second driving module or may be performed independently.

Subsequently, from the second step to the fourth step (Step 2 to Step 4), the lifting block 21 moves downward in stages by the second driving module. During each downward movement, the ejecting blocks sequentially move downward from the outermost ejecting block inward, with only the central ejecting block CB ultimately remaining in contact with the dicing tape T.

Thereafter, if the pickup of the semiconductor chip is completed, the process proceeds to a fifth step (Step 5), in which the central ejecting block CB also moves downward and further descends to a standby level. At this time, the second driving module moves upward to return to an original position thereof, while the first driving module moves downward to return to an original position thereof.

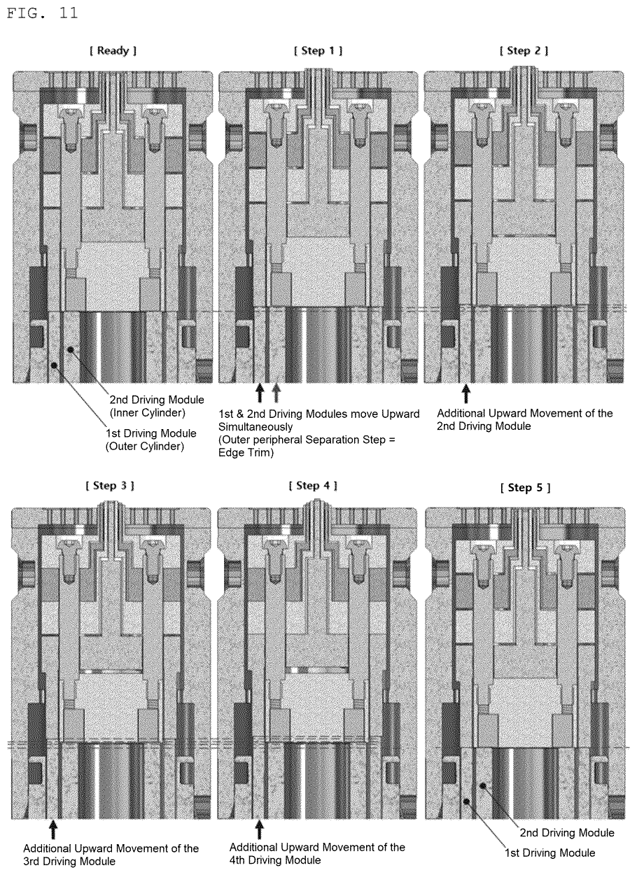

Additionally, by applying the above sequence in reverse, the ascending mode (refer to FIG. 11) can also be implemented, in which all of the ejecting blocks first move upward to the outer peripheral separation level, and as a first driving block moves upward, the second ejecting block BB to the central ejecting block CB simultaneously move further upward, and subsequently, the second ejecting block BB to the (n−1)th ejecting block sequentially move downward to the same level. Therefore, the present disclosure should not be excluded from being applicable not only to the same-level descending scheme (descending mode) (refer to FIG. 10) but also to the additional ascending and same-level descending scheme (ascending mode) (refer to FIG. 11). For reference, [A] in FIG. 10 illustrates a descending operation sequence (vertical level changes of ejecting blocks and vertical level changes of vertical driving blocks) in a three-stage ejector including three ejecting blocks (i.e., a first ejecting block, a second ejecting block, and a third ejecting block). [B] in FIG. 10 illustrates a descending operation sequence (vertical level changes of ejecting blocks and vertical level changes of vertical driving blocks) in a four-stage ejector including four ejecting blocks (i.e., a first ejecting block, a second ejecting block, a third ejecting block, and a fourth ejecting block). Furthermore, [A] in FIG. 12 illustrates an ascending operation sequence (vertical level changes of the ejecting blocks and vertical level changes of the vertical driving blocks) in the three-stage ejector including the three ejecting blocks (i.e., the first ejecting block, the second ejecting block, and the third ejecting block). [B] in FIG. 12 illustrates an ascending operation sequence (vertical level changes of the ejecting blocks and vertical level changes of the vertical driving blocks) in the four-stage ejector including the four ejecting blocks (i.e., the first ejecting block, the second ejecting block, the third ejecting block, and the fourth ejecting block).

FIG. 11 is a diagram illustrating a method (the present method) of driving the multi-stage ejector (a method of driving the multi-stage ejector which includes the descending mode or is operated in the descending mode) according to the present disclosure. The present method will be described with reference to FIG. 11. Before providing a detailed description, the mechanical configurations for implementing the present method are to be substituted with the above-described explanation of the present apparatus.

The present method may include step S1 (Step 1) of moving upward all of the ejecting blocks, each including the contact portion that comes into contact with the dicing tape T, so that the ejecting blocks are exposed outside the ejector hood 4, and pressing the dicing tape T from below. In step S1, the outer peripheral separation of the dicing tape T is performed, and the range of separation corresponds to the sum of areas of the contact portions of the ejecting blocks. Here, as mentioned above, both the second driving module, which moves the lifting block 21 upward, and the first driving module, which moves the central ejecting block CB upward, move upward. In this state, the vertical descending level of the ejecting blocks may be positioned at a standby position formed inside the ejector hood 4.

Next, the present method may include the step (a first descending step, which includes steps S2 to S4 in FIG. 11) of sequentially moving downward some of the ejecting blocks, starting from the first ejecting block OB, which is positioned at the outermost side among the plurality of ejecting blocks, to the ejecting block (i.e., the second ejecting block BB or the third ejecting block) positioned outward of the central ejecting block CB which is positioned at the innermost side.

More specifically, the present method may further include step S2 (Step 2) of moving downward the first ejecting block OB, positioned at the outermost side among the ejecting blocks. Referring to FIG. 11, in the second step (step S2), the first ejecting block OB, which is positioned at the outermost side, moves downward, causing the separation of the portion of the dicing tape T that has been in contact with the first ejecting block OB.

The present method may further include step S3 (Step 3) of moving downward the second ejecting block BB, positioned immediately inward of the first ejecting block OB. The present method may include step S4 (Step 4) of moving downward the third ejecting block, positioned immediately inward of the second ejecting block BB.

That is, in the third step (step S3), the second ejecting block BB, which is the second block, moves downward, and in the fourth step (step S4), the third ejecting block, which is the third block, moves downward, causing the sequential separation of the portions of the dicing tape T except for the portion that has been in contact with the first block.

The present method may further include the step (a second descending step) of moving downward the center ejecting block CB, positioned at the innermost side among the ejecting blocks. Ultimately, all of the ejecting blocks sequentially move downward to the same vertical level, which serves as the standby position inside the ejector hood 4.

Particularly, as described above, in the present apparatus, the lifting unit further includes the lifting block 21 provided below the central ejecting block CB. The stepwise downward movement of the ejecting blocks is achieved by the downward movement of the lifting block 21, and more specifically, the interlinked downward movement of the lifting block 21 and each of the ejecting blocks is carried out using the connecting pin 22, which is installed to connect each of the ejecting blocks to the lifting block 21.

The present disclosure, having the above-described configuration, steps, and features, primarily separates an outer periphery of dicing tape and then separates the dicing tape toward a center in stages, thereby enabling more reliable and easier separation of the dicing tape.

Furthermore, because only two vertical driving units are provided, the present disclosure has the effects of not only reducing costs compared to providing a vertical driving unit for each ejecting block but also simplifying a control algorithm of the vertical driving units.

In addition, since driving positions of the two vertical driving units are configured to be motion-controllable, the present disclosure has the effects of precisely adjusting the height of each of the ejecting blocks, where outer peripheral separation occurs, and selectively performing either a same-level descending operation or a same-level ascending operation, depending on a control sequence of the two vertical driving units.

The present disclosure described above with reference to the accompanying drawings may be variously modified and changed by those of ordinary skill in the art, and such modifications and changes that are not limited by the claims should be construed as being included in the scope of the present disclosure.

What is claimed is:

1. A multi-stage ejector comprising:
a plurality of ejecting blocks each including a contact portion that comes into contact with dicing tape;
a lifting unit comprising a driving module configured to move the ejecting blocks upward or downward; and
a restriction unit configured to limit a lifting height of each of the ejecting blocks,
wherein the ejecting blocks are configured such that
all of the ejecting blocks move upward so that the contact portions come into contact with the dicing tape, and then the ejecting blocks sequentially move downward, starting from an ejecting block having the contact portion positioned at an outermost side, to an identical vertical level (hereinafter, referred to as a descending mode), or
all of the ejecting blocks move upward so that the contact portions come into contact with the dicing tape, and then some of the ejecting blocks additionally move upward simultaneously, from a second ejecting block provided inward of a first ejecting block positioned at an outer side to a central ejecting block positioned at the innermost side, and thereafter, the ejecting blocks from the second ejecting block to the central ejecting block, sequentially move downward to the identical vertical level (hereinafter, referred to as an ascending mode).

2. The multi-stage ejector of claim 1, wherein a vertical descending level of the ejecting blocks is formed at a standby position formed in an ejector hood.

3. The multi-stage ejector of claim 2,
wherein the lifting unit further comprises a lifting block provided below the central ejecting block disposed at an innermost side among the ejecting blocks, and
wherein the driving module includes a first driving module configured to move the central ejecting block upward or downward, and a second driving module configured to move the lifting block upward or downward.

4. The multi-stage ejector of claim 3, wherein the lifting unit further comprises a connection pin installed to connect each of the ejecting blocks and the lifting block.

5. The multi-stage ejector of claim 1, wherein the restriction unit comprises a downward movement restriction unit configured to limit descent heights of the ejecting blocks, and a spacing restriction unit configured to limit a maximum spacing between the ejecting blocks.

6. The multi-stage ejector of claim 5,
wherein the lifting unit further comprises a connection pin installed to connect each of the ejecting blocks and the lifting block, and
wherein the downward movement restriction unit comprises a coupling element coupled to the connection pin, an elastic element configured to be compressed by the coupling element, and a support element provided under the elastic element.

7. The multi-stage ejector of claim 6,
wherein each of the plurality of ejecting blocks includes:
a disc that forms a base; and
an interlocking hole formed in the disc and provided for interlocking with an adjacent ejecting block,
wherein the interlocking hole includes an increased-width recess formed downward from an upper portion of the disc, and a reduced-width hole formed to penetrate both a bottom of the increased-width recess and a lower portion of the disc, the reduced-width hole having a width smaller than a width of the increased-width recess, and
wherein a vertical distance (hereinafter, referred to as an inner vertical distance) between a lower surface of the support element positioned in the increased-width recess of the interlocking hole of an inner ejecting block and the bottom of the increased-width recess of the interlocking hole of the inner ejecting block is greater than a vertical distance (hereinafter, referred to as an outer vertical distance) between a lower surface of the support element positioned in the increased-width recess of the interlocking hole of an outer ejecting block positioned outward of the inner ejecting block, and the bottom of the increased-width recess of the interlocking hole of the outer ejecting block.

8. The multi-stage ejector of claim 7, wherein the vertical distance (distance a) of a first ejecting block having the contact portion positioned at the outermost side among the plurality of ejecting blocks is a zero (0), the vertical distance of a second ejecting block disposed inward of the first ejecting block corresponds to distance a, and the vertical distance of the central ejecting block provided inward of the second ejecting block is twice distance a.

9. The multi-stage ejector of claim 5, wherein the spacing restriction unit comprises a bolt that passes through the first ejecting block and is fastened to the central ejecting block, or a bolt that passes through the second ejecting block and is fastened to the central ejecting block.

10. The multi-stage ejector of claim 9, wherein the bolt comprises a head portion having a diameter larger than a diameter of a through-hole formed in the first ejecting block or the second ejecting block, a body portion that is connected to the head portion and has a diameter smaller than or equal to the diameter of the through-hole, and a threaded portion that is connected to the body portion and engaged with a threaded hole formed in the central ejecting block.

11. The multi-stage ejector of claim 1, wherein when all of the ejecting blocks move upward, a peripheral side portion of a chip is separated from the dicing tape.

12. A method of driving a multi-stage ejector, the method comprising:
moving upward all of a plurality of ejecting blocks, each including a contact portion that comes into contact with dicing tape, so that the ejecting blocks are exposed outside an ejector hood, and pressing the dicing tape from below;
sequentially moving downward some of the plurality of ejecting blocks, starting from a first ejecting block disposed at an outermost side among the plurality of ejecting blocks to an ejecting block disposed outward of a central ejecting block disposed at an innermost side, by a lifting unit including a driving module configured to move the plurality of ejecting modules upward or downward; and
moving the central ejecting block downward by the lifting unit.

13. The method of claim 12, wherein a vertical descending level of the ejecting blocks is formed at a standby position formed in the ejector hood.

14. The method of claim 12, wherein the lifting unit further comprises a lifting block provided below the central ejecting block, and stepwise downward movement of the ejecting blocks is performed by moving the lifting block downward.

15. The method of claim 14, wherein interlocked downward movement of the lifting block and each of the ejecting blocks is performed using a connection pin installed to connect each of the ejecting blocks and the lifting block.
